(19) United States
(12) Patent Application Publication
(10) Pub. No.: US 2014/0009154 A1
(43) Pub. Date: Jan. 9, 2014

(54) METHOD FOR DETERMINING INFORMATION ABOUT DISTORTION AND CALIBRATION PHANTOM

(71) Applicant: SIEMENS AKTIENGESELLSCHAFT, Munich (DE)

(72) Inventors: Annemarie HAUSOTTE GEB BAKAI, Erlangen (DE); Patrick GROSS, Buckenhof (DE)

(21) Appl. No.: 13/922,689

(22) Filed: Jun. 20, 2013

(30) Foreign Application Priority Data
Jul. 3, 2012 (DE) 102012211507.2

(51) Int. Cl. G01R 33/58

(52) U.S. Cl. CPC G01R 33/58
USPC 324/309

(57) ABSTRACT

A method is disclosed for determining distortion information describing geometric distortion during the recording of magnetic resonance image data with a recording sequence, wherein a magnetic resonance image data set of at least one calibration phantom with a first marker structure having a defined geometry which is visible in magnetic resonance imaging is recorded. The at least one calibration phantom further includes a second marker structure having a defined geometry which is visible in computed tomography imaging. A computed tomography image data set of the calibration phantom is recorded and the distortion information is determined by a comparison of the magnetic resonance image data set with the computed tomography image data set, in particular at least partially automatically.

### PRIORITY STATEMENT

The present application hereby claims priority under 35 U.S.C. §119 to German patent application number DE 102012211507.2 filed Jul. 3, 2012, the entire contents of which are hereby incorporated herein by reference.

### FIELD

At least one embodiment of the invention generally relates to a method for determining distortion information describing geometric distortion during the recording of magnetic resonance image data with a recording sequence, wherein a magnetic resonance image data set of at least one calibration phantom with a first marker structure having a defined geometry which is visible in magnetic resonance imaging is recorded. At least one embodiment of the invention also generally relates to a calibration phantom for use in a method of this kind.

### BACKGROUND

Distortions, that is optical distortions, during the recording of magnetic resonance data are already widely known from the prior art. Optical distortions in magnetic resonance image data sets have numerous causes and are therefore dependent upon numerous different parameters, wherein they are known to be linked to the field strength, the acquisition protocol (the recording sequence) and the like. It is also known that the spatial accuracy of magnetic resonance image data decreases with the distance from the isocenter of the magnet. These distortions must always be taken into account when it is important to determine accurate positions of features visible in magnetic resonance image data.

Radiotherapy is a method of medical treatment with which a generally clearly defined pathology in the human body, in particular a tumor, is to be selectively exposed to harmful radiation, for example to destroy or reduce the size of the tumor or at least impede its growth. Here, it is essential that healthy areas adjoining the pathological area are not exposed to the harmful radiation. Therefore, it is fundamentally important to identify the target region to be irradiated and regions which are not to be irradiated with a high degree of accuracy and to know their spatial position. Nowadays it is known to use the imaging method ‘computed tomography’ (CT) for planning radiation treatment (radiation treatment planning). Computed tomography image data sets are used both to determine where the target regions and the organs at risk are located and to determine the impairment of the tissue with respect to ionizing radiation.

The essential property of computed tomography establishing it as a sort of “gold standard” is the fact that it may be assumed that the images are geometrically correct.

Magnetic resonance imaging (MR imaging) on the other hand offers high soft-tissue contrast and the possibility of also using functional imaging, in particular for determining functional parameters. Magnetic resonance imaging is, therefore, ideally suited to identifying target regions and organs at risk. However, magnetic resonance is subject to the aforementioned geometric distortions and this impedes the accuracy desired for the definition of radiation targets. In particular, the geometric distortions in magnetic resonance imaging are also determined by user settings, in particular the recording sequence selected, and so it is necessary to have a good understanding of these settings in order to be able actually to use the results of magnetic resonance image data for radiation treatment planning. This means quality assurance (QA) measures are required.

One possibility of circumventing the geometric distortions in magnetic resonance imaging is to see magnetic resonance imaging as an additional option to computed tomography imaging. Here, in the simplest possible form, computed tomography image data and magnetic resonance image data are displayed simultaneously but separately, wherein the person doing the planning, in particular a doctor, uses the contrast of the magnetic resonance imaging in his mind's eye when marking irradiation targets and regions to be avoided in the computed tomography image data, for example by outlining.

To achieve a higher degree of integration, it has been suggested that the magnetic resonance image data set be fused with the computed tomography image data set. At the same time, it is possible to visualize the quality of the fusion, for example by switching back and forth between the modalities, the use of different stages of transparency or different color charts or also by a chessboard approach, wherein the modalities are displayed on alternating square regions. This can be based on a rigid registration of the image data sets. In this case, the magnetic resonance imaging is once again seen as an addition to computed tomography imaging, wherein the person doing the planning determines the degree to which sufficient quality is ensured. The fusion in the context of the registration can be optimized in order to minimize the difference between the magnetic resonance image data set and the computed tomography image data set with respect to a metric, for example a mutual-information measurement or a mutual-entropy measurement. Here, once again, computed tomography is considered to be the “gold standard” while magnetic-resonance distortions are “compensated” by the fusion.

If different imaging techniques, in particular different recording sequences, are to be evaluated in magnetic resonance imaging and quality assurance is to be repeated regularly, it is possible that non-quantitative approaches of this kind will not suffice. It may also be desirable to use the results of a quality assurance measure in algorithms that correct magnetic resonance distortions (distortion correction), for example even before the fusion, in particular the rigid registration of magnetic resonance image data sets and computed tomography image data sets. For this, it is known to use calibration phantoms, which have already been described in the prior art. These calibration phantoms have a marker structure which is visible in magnetic resonance imaging with a geometry that is known in principle and is used as standard in order also to determine deviations from this standard geometry as distortions in magnetic resonance image data of the calibration phantom in quantitative terms.

A major problem with calibration phantoms of this kind is that even these may not be accurate enough, i.e. in particular the standard geometry of the marker structure used for the comparison is a false assumption. Temperature variations, mechanical forces, aging processes and the like can result in changes to the geometry in the calibration phantom. For example, the use of a “reliable” magnetic resonance recording sequence has been suggested in order to perform a recalibration. A “reliable” recording sequence of this kind is one that is inherently less susceptible to distortions. Nevertheless, deviations also occur in this case so that the precision of calibration measurements of this kind may not be sufficient for determining distortion correction information, in particular with respect to radiation treatment planning.

### SUMMARY

At least one embodiment of the invention is directed to determining a possibility for determining distortion information identifying the geometric distortions in magnetic resonance imaging with specific recording sequences more accurately and in particular also in a more intuitively understandable way, in particular with respect to carrying out radiation treatment planning.

According to at least one embodiment of the invention, a method is provided wherein a calibration phantom is used, which has a second marker structure having a defined geometry which is visible in computed tomography imaging, wherein a computed tomography image data set of the calibration phantom is recorded and the distortion information is determined by a comparison of the magnetic resonance image data set with the computed tomography image data set, in particular at least partially automatically.

According to at least one embodiment of the invention, therefore, it is suggested that a calibration phantom be used which has not only the first marker structure, which is visible in magnetic resonance imaging, but also a—obviously also geometrically clearly defined with respect to the first marker structure—second marker structure, which is visible in computed tomography imaging. Therefore, instead of using a standard geometry, which, due to a wide variety of effects, can be a false assumption, the present invention suggests that near real-time recorded current computed tomography image data of the calibration phantom be used as a basis for the comparison since computed tomography is known for its geometrically accurate imaging. This provides a much more reliable basis for the comparison and therefore the determination of the distortion information. Precisely in the context of radiation treatment planning, in which computed tomography is already used as a modality and is therefore available, this is an advantageous extension and improvement for the determination of distortion information.

In addition to the method, at least one embodiment of the present invention also generally relates to a calibration phantom for use in a method according to at least one embodiment of the invention with a first marker structure having a defined geometry which is visible in magnetic resonance imaging and a second marker structure having a defined geometry which is visible in computed tomography imaging. All possible embodiments with respect to the calibration phantom in the context of the description of the method according to the invention can also be transferred to the calibration phantom according to at least one embodiment of the invention so that it can be advantageously used to generate more accurate distortion information which can be represented intuitively and is simple to determine for one or more recording sequences. In particular, the embodiment of the calibration phantom can be selected such that the first marker structure is also the second marker structure and specific materials can be introduced or material transitions can be created at defined positions which can provide information on distortions that occur in magnetic resonance imaging with the recording sequence. It is also expedient, as described above, to use surface markings, for example aiming crosses, for use with laser positioning devices and to embody the marker structures as structures that can intuitively be identified and evaluated, for example lattices.

The method according to at least one embodiment of the invention can be implemented by at least one computing device, in particular a computing device for performing the automatic steps for determining the distortion information. It is also possible for control devices to participate in a system implementing the method according to at least one embodiment of the invention, in particular control devices of the magnetic resonance device and/or the computed tomography device used, said control devices being able to be embodied to control the recording of the image data sets.

### BRIEF DESCRIPTION OF THE DRAWINGS

Further advantages and details of the present invention can be derived from the example embodiments described below and with reference to the drawing, which shows:

FIG. 1 a flow diagram of the method according to an embodiment of the invention,

FIG. 2 a calibration phantom according to an embodiment of the invention,

FIG. 3 a schematic sketch of a possible joint representation of image data, and

FIG. 4 a system for performing the method according to an embodiment of the invention.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

According to at least one embodiment of the invention, a method is provided wherein a calibration phantom is used, which has a second marker structure having a defined geometry which is visible in computed tomography imaging, wherein a computed tomography image data set of the calibration phantom is recorded and the distortion information is determined by a comparison of the magnetic resonance image data set with the computed tomography image data set, in particular at least partially automatically.

According to at least one embodiment of the invention, therefore, it is suggested that a calibration phantom be used which has not only the first marker structure, which is visible in magnetic resonance imaging, but also a—obviously also geometrically clearly defined with respect to the first marker structure—second marker structure, which is visible in computed tomography imaging. Therefore, instead of using a standard geometry, which, due to a wide variety of effects, can be a false assumption, the present invention suggests that near real-time recorded current computed tomography image data of the calibration phantom be used as a basis for the comparison since computed tomography is known for its geometrically accurate imaging. This provides a much more reliable basis for the comparison and therefore the determination of the distortion information. Precisely in the context of radiation treatment planning, in which computed tomography is already used as a modality and is therefore available, this is an advantageous extension and improvement for the determination of distortion information.

Therefore, at least one embodiment of the invention suggests a calibration phantom that may in particular be used in the context of radiation therapy, which is, on the one hand, embodied in order to be able to measure and calibrate geometric distortions in magnetic resonance imaging, but simultaneously can also itself be measured or calibrated by the computed tomography imaging. To this end, the calibration phantom of at least one embodiment includes:

a clearly defined geometric first marker structure, which is visible in magnetic resonance imaging thus enabling an evaluation of the magnetic resonance distortions,

a clearly defined geometric second marker structure, which is visible under computed tomography imaging thus enabling an evaluation of the actual geometrical conditions of the calibration phantom (phantom distortions),

wherein the first marker structure is geometrically linked to the second marker structure, which means that its spatial relationship is known.

Here, care should always be taken to ensure that the first and second marker structures do not generate any disruptive artifacts in the image data sets of the respective other modality. For example, small metal markers can be used to visualize positions in computed tomography, wherein care should be taken to ensure that non-ferromagnetic materials and rather small structures are used so that streak or star artifacts are avoided in computed tomography and simultaneously distortions due to the magnetic resonance gradients are avoided as is radio-frequency heating induced by the recording sequence. However, and this will be dealt with in more detail below, it can also be conceivable to introduce such “disruptive” materials in a controlled way, in particular for the magnet resonance, to enable their effects to be observed; this will be dealt with in more detail below.

In a particularly advantageous embodiment of the present invention, it can be provided that a calibration phantom is used, with which the first marker structure corresponds to the second marker structure. This means, therefore, that the first marker structure is simultaneously also the second marker structure. In this way, overall only one marker structure has to be provided in the calibration phantom which can be used simultaneously as the first marker structure and the second marker structure. Here, one suitable approach is to place, for example, a structural body, for example a three-dimensional lattice, which can be made of plastic and/or ceramic, in a liquid, for example water, inside the phantom since the differences can be visible in both computed tomography imaging and in magnetic resonance imaging.

The general construction of phantoms and the structure of markers for magnetic resonance imaging and computed tomography imaging is already known in the prior art, wherein the present invention suggests that the procedures known in principle for the individual modalities be combined in a common calibration phantom. This usually creates contrast transitions that are visible in magnetic resonance imaging and/or computed tomography imaging.

Obviously, it is also possible to use an objectively and spatially separate first marker structure and second marker structure, wherein then, as explained above, the geometric relationship between the marker structures has to be known so that a desired positioning of the first marker structure can be derived from known position data for the second marker structure.

A lattice structure can be used as the first marker structure and/or second marker structure and/or the first marker structure and/or the second marker structure can contain a pattern and/or a symbol. In particular when a representation is to be derived from the image data sets in order to be used to evaluate the geometric distortions, it is expedient to use structures on which a person can recognize deviations as simply and intuitively as possible. If in one embodiment of the method according to the invention, the evaluation is focused on an automatic quantification of the distortion information, structures are suitable which, or the deviations of which, are easy to describe mathematically.

In a particularly expedient way, a calibration phantom can be used in which a material causing distortions in magnetic resonance images and/or a material change causing distortions in magnetic resonance images is provided at a known geometric position relative to the marker structures. It is, therefore, possible selectively to introduce materials or transitions between materials, for example susceptibility changes, in the calibration phantom, obviously at a clearly defined position with respect to the marker structures in order selectively to check recording sequences to see whether there are any distortions. In particular, it is thus expedient, for example to introduce materials with different susceptibility or different chemical shift as features to the calibration phantom in known positions. Here, it is particularly advantageous to select materials or material transitions which could also occur in a patient to be examined. It is, for example, expedient to use regions which are filled with air, fat and/or oil in order, for example, to simulate air in the case of images in the region of the colon and the like. Correspondingly, it is also possible to draw conclusions as to whether the recording sequence reacts sensitively to those features which influence the geometric distortion.

It is further conceivable to use a calibration phantom comprising at least one metal part in a defined position. Therefore, metal itself can be used in a controlled way as an additional feature in a calibration phantom since metals can quite possibly occur in the human body, for example in the form of hip implants, inserted surgical screws and the like. It is then possible to check, for example, which magnetic resonance sequences are better to use with metal structures and the like.

It is also preferably provided that a calibration phantom with at least one surface marking, in particular an aiming cross, is used, wherein the positioning of the calibration phantom in a magnetic resonance device and/or a computed tomography device is performed using a laser positioning device assigned to the respective imaging device. Since both magnetic resonance devices and computed tomography devices with laser positioning devices of this kind are known, it can be expedient also to equip the calibration phantom used for the use of such laser positioning devices in order to simplify the workflow with the calibration phantom. For example, aiming crosses provided on the upper surface of the calibration phantom are conceivable.

For further, automatic evaluation with respect to the determination of the distortion information, it can be provided that the magnetic resonance image data set and the computed tomography image data set are registered rigidly with one another. For this, it is possible to use a computing device on which registration algorithms that are known in principle, which can be oriented, for example toward changes in contrast and the like, are stored as software means, which evaluate the magnetic resonance image data set and the computed tomography image data set. Registration algorithms of this kind, which can, for example, also work with mutual information and/or mutual entropy measurements, are extensively known in the prior art and do not need to be explained in any further detail here. It is relevant that only rigid registration takes place in order to obtain the information on geometric distortions as accurately as possible. Following registration, the two image data sets are in the same coordinate system and can, therefore, be further processed jointly under clear assignments.

In an advantageous embodiment of the present invention, it can be provided that a representation derived from the registered image data sets is generated and sent to a user to display. This in particular takes place so that the user can evaluate distortions in the magnetic resonance image data set visually. The approach that a representation is generated from a preliminary evaluation of the image data sets from which the final evaluation of the geometric distortion is performed is based on the fundamental knowledge that, in many cases, it can be more efficient to grant a user, for example a doctor planning radiation therapy, intuitive access to an evaluation of the reliability of a recording sequence with respect to geometric features. A distortion correction, which in the context of the present invention—this will be dealt with in more detail below—is in principle also, optionally even additionally, conceivable, would take place alone in the background, imperceptibly to a user so that the user is as little able to evaluate its quality as to assess whether it has really corrected all distortions, i.e. geometric distortions. Here, it appears expedient to provide the user with an aid in the form of the visual representation with which he can evaluate specific possible recording sequences to see whether they are suitable for his special application, in particular with respect to geometric accuracy. For example, representations of this kind based on the calibration phantom can be determined and stored for different recording sequences so that, if he wishes to evaluate the geometric distortions of the recording sequences intuitively, a user can call these up and evaluate them visually as appropriate. Here it is particularly advantageous for, as already described, features, for example specific materials, to be provided at defined positions, which beyond the usual imaging behavior, show the reaction of the recording sequence on the features influencing the distortion. Overall, therefore, it can be established that it can be more expedient to select a robust recording sequence for the recording of magnetic resonance image data, which for the special application, for example a special imaging region in a special patient, is suitable to use as a correction that only runs in the background which would not be part of this evaluation.

Here, it is expedient for the representation to comprise adjacently arranged image data of the magnetic resonance image data set and of the computed tomography image data set, in particular in the form of two adjacently arranged images of the image data sets and/or in the style of a chessboard, with which the fields are alternately assigned image areas of the magnetic resonance image data set and of the computed tomography image data set so that adjacently arranged image areas relate to the same geometric region of the calibration phantom. Therefore, it is possible, by means of directly adjacently arranged images, of which one, namely the computed tomography image, shows the real geometric conditions, while the other, the magnetic resonance image, can contain distortions, to assist a comparison by the user. Here, the aforementioned chessboard representation has been found to be particularly advantageous since here adjacent small sections of the same region can always be directly compared. The user is therefore provided with an excellent tool for evaluating any distortions present. However, it is obviously also conceivable for the magnetic resonance image data set and the computed tomography image data set to be fused and the fused representation to be displayed. Fused representations of this kind, which can, for example, be generated by superimpositions, are known in principle in the prior art and can also be used in the context of the present invention. This enables a clear distinctiveness of the images to be ensured, for example, in that transparencies are assigned, different colors are used and the like.

As already mentioned, such representations have been found to be a particularly expedient tool for the evaluation of the precision of locations of magnetic resonance image data sets, in particular if it is necessary to distinguish between different recording sequences. As already explained, the accuracy of the location of magnetic resonance image data sets, particularly in the field of radiation treatment planning, is extremely important. Therefore, in a particularly advantageous embodiment of the present invention, it can be provided that the representation is displayed jointly with magnetic resonance image data recorded later with the same recording sequence, in particular jointly with computed tomography data of the same object recorded later and/or in the context of radiation treatment planning. During the evaluation of the susceptibility to distortion of recorded magnetic resonance image data, it is expediently possible to keep the representation as an excellent evaluation tool and to display it to the user when required. This is extremely useful, particularly in radiation treatment planning, since the representation gives a clear indication of the degree to which the results of the magnetic resonance image data set need to be taken into account when planning radiation targets and regions which should not be exposed. Reference is made to the fact that it is obviously also possible in principle to keep a plurality of representations for different recording sequences so that, as already explained, for a special situation, in particular a special imaging task, it is possible to select a particularly suitable recording sequence with respect to the geometric distortions.

It is obviously also conceivable, by evaluation of the magnetic resonance image data set and of the computed tomography image data set to determine additional information and integrate it in the representation. For example, it is possible, to use algorithms highlighting the marker structures or to localize and superimpose the marker structures inside the image data sets, in particular by segmentation and/or edge detection algorithms. If a calibration phantom with special features, for example materials or material transitions, which encourage distortions, are used, these regions can also be detected, highlighted and/or labeled in order to assist the user during the acquisition of the information contained in the representation. Evidently, a wide variety of possibilities are conceivable for embodying the representation so that it can be acquired as intuitively as possible by the user. At this point, reference is made once again to the fact that, for the purposes of the present invention, the representation to be evaluated by a user itself ultimately represents (automatically determined) distortion information since information on distortion is easily obtained therefrom.

Alternatively or additionally, in the context of at least one embodiment of the present invention, it is also possible for determining and displaying representations to determine quantitative, optionally spatially resolved, distortion information by comparing the marker structures visible in the rigidly registered image data sets and to display this to a user and/or use it to correct magnetic resonance image data recorded subsequently with the recording sequence. Due to the exact reference from the computed tomography measurement, it is also possible in the context of the present invention to obtain improved quantitative information on distortions, which particularly advantageously can also be determined with spatial resolution, for example in the form of a field of displacement vectors and the like. Quantitative distortion information of this kind can also be a part of or supplement the representation discussed above or be offered as supplementary information supplementary to a representation. One special case of quantitative, spatially resolved distortion information of this kind is distortion correction information, which is used in the context of a distortion correction as is known in principle in the prior art and does not need to be described in any more detail here. It is also possible in the context of the present invention to determine distortion correction information as distortion information. Distortion correction information of this kind can, for example, be used during the later recording of further useful magnetic resonance image data, in particular in the context of radiation treatment planning. Then, before a registration or fusion of a later-recorded magnetic resonance image data set with a later-recorded computed tomography image data set is performed, distortion correction can be performed on the later-recorded magnetic resonance image data set. However, it is also obviously possible to use distortion correction of this kind on later-recorded useful magnetic resonance image data sets, for example diagnostic magnetic resonance image data sets outside radiation treatment planning as well.

Here, it is in particular conceivable that, with the aid of suitable algorithms, the marker structures in the image data sets are localized and depicted as a model. Therefore, if the first marker structure is also simultaneously the second marker structure, the deviations between the models can be viewed directly (and therefore determined), otherwise, due to the known geometric relationship, a desired model for the first marker structure is derived from the computed tomography image data between the marker structures and said desired model can be compared with the measured model of the first marker structure. In particular, it is attempted to use algorithms to determine how the model of the first marker structure can be depicted on the desired model or the model of the second marker structure. Therefore, the use of models of this kind enables a simpler mathematical description of the relationships and therefore also a simpler evaluation of the image data sets.

In a further embodiment of the present invention, it can be provided that the determination of the distortion information is repeated cyclically. Since, on the one hand, the calibration phantom can be subject to ageing phenomena but, on the other, this can also apply for the magnetic resonance device itself with respect to smaller changes, it is expedient to keep the distortion information up-to-date at all times. For example, it can be provided that the determination of the distortion information is repeated daily or weekly or monthly.

As explained many times above, it is particularly advantageous for the distortion information to be determined for different recording sequences. Different magnetic resonance recording sequences have different sensitivities to geometric distortion or display different reactions to certain materials, susceptibility transitions, chemical shifts and the like so that it is expedient to retain, distortion information for as many of these embodiments as possible. This applies both for representations provided for intuitive evaluation by a user and for quantitative information occurring, for example, in the form of distortion correction information. In this way, it is in particular possible to evaluate different recording sequences quantitatively, with suitably embodied phantoms also with respect to a specific imaging task.

In an expedient development of at least one embodiment of the present invention, it is possible to use software used in the context of radiation treatment planning for the joint evaluation of magnetic resonance image data sets and computed tomography image data sets to determine the distortion information, in particular the representation. Since it is already usual, in particular in radiation treatment planning, to record computed tomography image data sets and magnetic resonance image data sets of an object in order then to be able to view them jointly, computer programs which perform a rigid registration between a computed tomography image data set and a magnetic resonance image data set in order to generate a representation therefrom which enables both image data sets to be viewed jointly, in particular by generating a fused representation, are already common. Software of this kind can also be advantageously used in the context of the present invention so that when the present invention is applied in the context of radiation treatment planning, the representations formed are also already known to the person skilled in the art and can be directly compared with the representations in which he then performs the radiation treatment planning.

In addition to the method, at least one embodiment of the present invention also generally relates to a calibration phantom for use in a method according to at least one embodiment of the invention with a first marker structure having a defined geometry which is visible in magnetic resonance imaging and a second marker structure having a defined geometry which is visible in computed tomography imaging. All possible embodiments with respect to the calibration phantom in the context of the description of the method according to the invention can also be transferred to the calibration phantom according to at least one embodiment of the invention so that it can be advantageously used to generate more accurate distortion information which can be represented intuitively and is simple to determine for one or more recording sequences. In particular, the embodiment of the calibration phantom can be selected such that the first marker structure is also the second marker structure and specific materials can be introduced or material transitions can be created at defined positions which can provide information on distortions that occur in magnetic resonance imaging with the recording sequence. It is also expedient, as described above, to use surface markings, for example aiming crosses, for use with laser positioning devices and to embody the marker structures as structures that can intuitively be identified and evaluated, for example lattices.

The method according to at least one embodiment of the invention can be implemented by at least one computing device, in particular a computing device for performing the automatic steps for determining the distortion information. It is also possible for control devices to participate in a system implementing the method according to at least one embodiment of the invention, in particular control devices of the magnetic resonance device and/or the computed tomography device used, said control devices being able to be embodied to control the recording of the image data sets.

The method according to the example embodiments described below are used for the determination of distortion information describing the geometric distortions that occur with one or more specific recording sequences of a magnetic resonance device as reliably and intuitively understandably as possible. A calibration phantom is used that is described in more detail below with respect to FIG. 2 and which has clearly defined geometric marker structures which are also at least partially visible in computed tomography imaging so that, in steps 1 and 2, the calibration phantom can be recorded with both a computed tomography device and a magnetic resonance device. This results in a magnetic resonance image data set (or a magnetic resonance image data set for each recording sequence) and a computed tomography image data set, which indicate clearly and comparably the geometric relationships within the calibration phantom so that the distortion information can be derived by a comparison of the image data sets.

FIG. 2 shows an example embodiment of a calibration phantom 3 that can be used in the method according to the invention. In the present case, this comprises a housing 4 filled with a liquid 5, here water. A geometric marker structure 7 is provided inside the housing in the form of a three-dimensional lattice 6, which here functions as both a first marker structure 7 and a second marker structure 7, which means that the lattice 6 is clearly visible in both a magnetic resonance image data set and a computed tomography image data set. In order to generate the necessary contrasts, in this case the marker structure is made of plastic, but ceramics are also conceivable.

In addition to the marker structure 7, the calibration phantom 3 contains containers 8, which are also positioned in a clearly geometrical way with respect to the marker structure 7 and materials 9 of which it is known that they can result in geometric distortions during magnetic resonance imaging. In the present case, materials with different susceptibilities are used, here one container 8 with air and a further container 8 with fat and/or oil. The resulting differences in susceptibility (or also material transitions) can trigger geometric distortions with many recording sequences. Therefore, a measurement on the calibration phantom 3 can give an indication of how sensitive the recording sequence is for the materials 9.

Here, a metal object 10 is provided as further material inside the calibration phantom 3, with which, for example, it is possible to check the degree to which the recording sequence reacts sensitively to metal.

In addition, a surface marking 11 is provided on the surface of the calibration phantom 3, here in the form of an aiming cross, which is employed in conjunction with laser positioning devices, which are used on both magnetic resonance devices and computed tomography devices, in order to achieve a desired position and alignment of the calibration phantom 3. A plurality of such surface markings 11 can be provided.

In principle, it is obviously also conceivable to use two marker structures 7, wherein in each case one is assigned a modality, wherein it is then necessary to ensure that the spatial relationship between the marker structures 7 is completely known so that a desired position for the first marker structure assigned to magnetic resonance imaging can be followed from a measured position of the second marker structure assigned to computed tomography imaging. In addition, marker structures 7 do not have to be three-dimensional lattices but can be any other type of structure, for example such that contain specific shapes and/or symbols in which changes can be noted intuitively including on viewing.

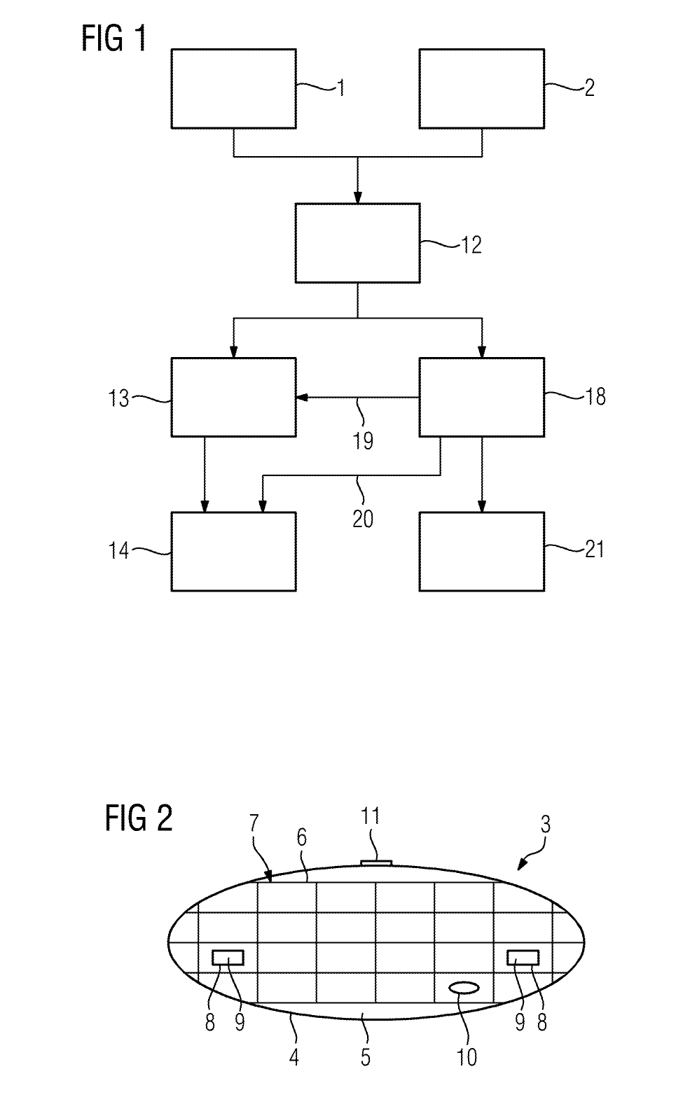

To return to FIG. 1, consequently in step 1 initially a computed tomography image data set of the calibration phantom 3 is taken with a computed tomography device. Since computed tomography imaging is known for geometrically very exact depictions, the corresponding computed tomography image data set depicts the actual geometric relationships inside the calibration phantom 3, which therefore forms a measured reference which also takes into account ageing phenomena and the like.

In a step 2, a magnetic resonance device records, close to real-time, a magnetic resonance image data set of the same calibration phantom 3, which contains geometric distortions (distortions) corresponding to the recording sequence and the magnetic resonance device. Distortion information should now be determined herefrom by comparison.

To this end, initially in a step 12, when the image data sets are present on a joint computing device, an automatic, rigid registration of the computed tomography image data set with the magnetic resonance image data set is provided. Algorithms known in principle in the prior art can be used for this. Therefore, following the rigid registration, it is possible to draw conclusions regarding corresponding features.

The further automatic evaluation with respect to the determination of the distortion information can be performed in a different way, wherein it is initially expedient, and also preferred according to at least one embodiment of the invention, in step 13, to derive from the registered image data sets a representation from which it is particularly easy to derive distortions and geometric distortions. A representation of this kind is displayed to a user in a step 14 so that the user is able visually to evaluate the distortions in the magnetic resonance image data set with this recording sequence. Here, the suggested examination is anyway expediently performed for a plurality of recording sequences, in particular all recording sequences provided on a magnetic resonance device so that ultimately a plurality of magnetic resonance image data sets are available which can be correspondingly registered in step 12 and from which corresponding representations are then derived in step 13.

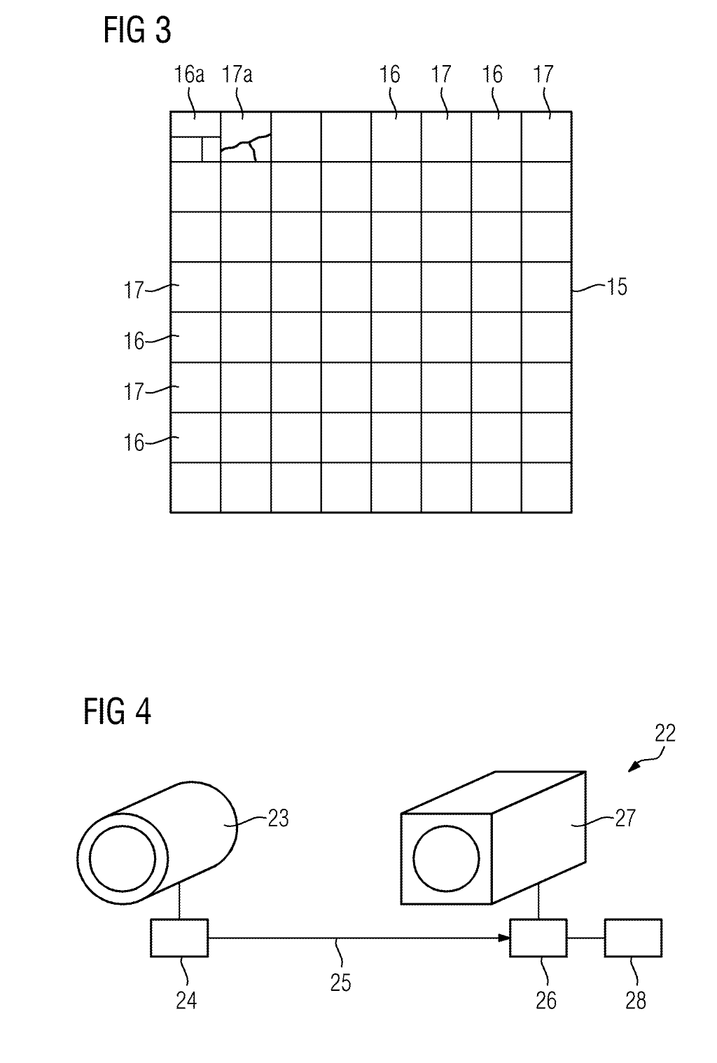

FIG. 3 is a schematic diagram of an example representation 15. Here, a sort of chessboard pattern is used, wherein in continuous alternation computed tomography image data are shown in representation regions 16 and magnetic resonance image data in representation regions 17. Here, the image areas are always selected such that the same features of the calibration phantom 3 are shown in adjacent representation regions in a line. This is indicated by way of example for the representation regions 16a and 17a. A straight course, therefore a realistic reproduction of a part of the lattice 6, can be identified in the representation region 16a. The same section can also be identified in the representation region 17a, but it is distorted due to the use of magnetic resonance imaging. An observer can now compare image areas in the representation regions 16a, 17a in order to draw conclusions regarding the degree of distortion in this region.

At this point, reference is made once again to the fact that obviously it is possible for a more extensive evaluation of the image data sets to take place in step 13, for example for clearer emphasis of the marker structure 7 in the image data sets, for labeling and emphasizing the materials 9, 10 and the like.

Such representations 15 represent an excellent tool if there is a requirement, for example, to preselect a recording sequence for magnetic resonance imaging or an evaluation of the image fidelity of a magnetic resonance imaging process that has already been performed. For example, if namely a specific imaging task is set, a user can view representations 15 for different recording sequences and evaluate whether they are suitable for fulfilling the imaging task with the fewest possible geometric distortions or the fewest possible disruptive geometric distortions. It is then possible to select a recording sequence accordingly. However, it is also conceivable, in particular in the context of radiation treatment planning, for a representation corresponding to the representation 15 to show the representation 15. In other words, then at least one later-recorded magnetic resonance image data set of the object and one later-recorded computed tomography image data set of the object is available. A user is then able to evaluate with reference to the representation 15, which then functions as a reference representation, how reliably the magnetic resonance image data set of the object is with respect to distortions.

Here it is also particularly expedient for the representation 15 to be generated in the same or similar way as a representation of image data sets of the object in that the same software is used to generate the representation (and also for the registration).

However, alternatively or additionally, see FIG. 1 again, a determination of quantitative, in particular spatially-resolved distortion information is conceivable, step 18. In this exemplary embodiment, it is provided that in each case a model of the marker structure 7 is derived from the respective image data sets. This is possible without problems since the marker structure 7 is selectively embodied such to offer clear contrasts for both modalities. Correspondingly, a quantitative evaluation is now also possible if the computing device attempts, by means of suitable algorithms, to depict the model of the marker structure 7 originating from the magnetic resonance image data set on the model of the marker structure 7 originating from the computed tomography image data set. In particular, it is possible, for example, to determine a displacement vector field. In a similar way, image analysis algorithms can also be used to achieve quantitative evaluations with respect to the materials 9, 10. The quantitative distortion information obtained can obviously, see arrow 19, also be used in order to improve the generation of the representation in step 13 and to supplement information, in addition, the quantitative distortion information, arrow 20, can be displayed jointly with a representation such as the representation 15.

However, it is also obviously also conceivable for distortion correction information to be determined as distortion information, wherein said distortion correction information can be used in a distortion correction method known in principle from the prior art, step 21.

Finally, FIG. 4 shows a system 22 with which the method according to at least one embodiment of the invention can be performed. This shows a computed tomography device 23, with which the computed tomography image data set can be recorded. The recording can, for example, be controlled by a control device 24 of the computed tomography device 23. After the recording, the control device 24 of the computed tomography device 23 can transmit the computed tomography image data set according to the arrow 25 to a control device 26 of a magnetic resonance device 27, with which at least one magnetic resonance image data set of the calibration phantom 3 can then be recorded using the at least one recording sequence. The control device 26, which then contains the computed tomography image data set, can then also be used as a computing device for performing the automatic evaluation steps of the method according to the invention (steps 12, 13, 14, 18, 21). Correspondingly, the control device 26 or the magnetic resonance device 27 can generally be assigned a display device 28 in order to be able to display representations, for example the representation 15.

Although the invention was illustrated and described in detail by the preferred example embodiment, the invention is not restricted by the disclosed examples and other variations may be derived therefrom by the person skilled in the art without departing from the scope of protection of the invention.

What is claimed is:

1. A method for determining distortion information describing geometric distortion during a recording of magnetic resonance image data with a recording sequence, the method comprising:
recording a magnetic resonance image data set of at least one calibration phantom with a first marker structure having a defined geometry which is visible in magnetic resonance imaging, the at least one calibration phantom including a second marker structure having a defined geometry which is visible in computed tomography imaging;
recording a computed tomography image data set of the at least one calibration phantom; and
determining the distortion information by a comparison of the magnetic resonance image data set with the computed tomography image data set.

2. The method of claim 1, wherein the at least one calibration phantom includes the first marker structure which corresponds to the second marker structure.

3. The method of claim 1, wherein at least one of the first marker structure and the second marker structure at least one of is a lattice structure and contains at least one of a pattern and a symbol.

4. The method of claim 1, wherein, regarding the at least one calibration phantom, at least one of a material causing distortions in magnetic resonance images and a material change causing distortions in magnetic resonance images is provided at a known geometric position relative to the marker structures.

5. The method of claim 1, wherein the at least one calibration phantom includes at least one metal part in a defined position.

6. The method of claim 1, wherein the at least one calibration phantom includes at least one surface marking, and wherein the positioning of the calibration phantom in at least one of a magnetic resonance device and a computed tomography device is performed using a laser positioning device assigned to a respective one of the magnetic resonance device and computed tomography device.

7. The method of claim 1, wherein the magnetic resonance image data set and the computed tomography image data set are registered rigidly with one another.

8. The method of claim 7, wherein a representation derived from the recorded image data sets is generated and shown to a user in such a way that the user can evaluate distortions in the magnetic resonance image data set visually.

9. The method of claim 8, wherein the representation comprises adjacently arranged image data of the magnetic resonance image data set and of the computed tomography image data set.

10. The method of claim 8, wherein the representation is shown jointly with magnetic resonance image data recorded later with the same recording sequence.

11. The method of claim 7, wherein the comparison of the marker structures visible in the rigidly recorded image data sets enables quantitative, optionally spatially resolved, distortion information to be determined and at least one of displayed to a user and used to correct magnetic resonance image data recorded subsequently with the recording sequence.

12. The method of claim 11, wherein distortion correction information is determined as distortion information.

13. The method of claim 1, wherein at least one of the determination of the distortion information is repeated cyclically, and distortion information is determined for different recording sequences.

14. The method of claim 1, wherein, for determining the distortion information, software used in the context of the radiation treatment planning for the joint evaluation of magnetic resonance image data sets and computed tomography image data sets is employed.

15. A calibration phantom for use in the method of claim 1, comprising:
a first marker structure having a defined geometry visible in magnetic resonance imaging and a second marker structure having a defined geometry visible in computed tomography imaging.

16. The method of claim 1, wherein the determining of the distortion information is performed at least partially automatically.

17. The method of claim 2, wherein at least one of the first marker structure and the second marker structure at least one of is a lattice structure and contains at least one of a pattern and a symbol.

18. The method of claim 2, wherein, regarding the at least one calibration phantom, at least one of a material causing distortions in magnetic resonance images and a material change causing distortions in magnetic resonance images is provided at a known geometric position relative to the marker structures.

19. The method of claim 6, wherein the at least one surface marking is an aiming cross.

20. The method of claim 9, wherein the representation comprises adjacently arranged image data of the magnetic resonance image data set and of the computed tomography image data set, at least one of in a form of two adjacently arranged images of the image data sets and in a style of a chessboard with which image areas of the magnetic resonance image data set and of the computed tomography image data set are assigned to the fields in an alternating fashion so that adjacently arranged image areas relate to the same geometric region of the calibration phantom.

21. The method of claim 9, wherein the representation comprises adjacently arranged image data of the magnetic resonance image data set and of the computed tomography image data set, and the magnetic resonance image data set and the computed tomography image data set are fused and the fused representation is shown.

22. The method of claim 10, wherein the representation is shown jointly with computed tomography data of the same object recorded at least one of later and in the context of radiation treatment planning.
